(19) United States
(12) Patent Application Publication
(10) Pub. No.: US 2025/0336687 A1
(43) Pub. Date: Oct. 30, 2025

(54) PACKAGES WITH IMPLANTATION

(71) Applicant: Taiwan Semiconductor Manufacturing Co., Ltd., Hsinchu (TW)

(72) Inventors: Ming-Tsu Chung, Hsinchu (TW); Yung-Chi Lin, Su-Lin City (TW); Yan-Zuo Tsai, Hsinchu (TW); Yang-Chih Hsueh, Hsinchu (TW); Ming-Shih Yeh, Hsinchu (TW)

(21) Appl. No.: 19/264,174

(22) Filed: Jul. 9, 2025

Related U.S. Application Data
(63) Continuation of application No. 18/513,957, filed on Nov. 20, 2023.
(60) Provisional application No. 63/532,452, filed on Aug. 14, 2023.

(51) Int. Cl. H01L 21/56; H01L 23/00; H01L 23/31; H01L 23/48; H01L 23/498; H01L 23/538; H01L 25/065

(52) U.S. Cl. CPC H01L 21/56; H01L 23/3128; H01L 23/481; H01L 23/49894; H01L 23/5383; H01L 24/08; H01L 24/80; H01L 25/0652; H01L 2224/08145; H01L 2224/08225; H01L 2224/80895; H01L 2224/80896

(57) ABSTRACT

A method includes bonding a device die onto a package component. The device die includes a semiconductor substrate, and a through-via extending into the semiconductor substrate. The method further includes depositing a dielectric liner lining sidewalls of the device die, depositing a dielectric layer on the dielectric liner, and planarizing the dielectric layer and the device die. Remaining portions of the dielectric liner and the dielectric layer form a gap-filling region, and a top end of the through-via is revealed. An implantation process is performed to introduce a stress modulation dopant into at least one of the dielectric liner and the dielectric layer. A redistribution line is formed over and electrically connecting to the through-via.

### PRIORITY CLAIM AND CROSS-REFERENCE

This application is a continuation of U.S. patent application Ser. No. 18/513,957, filed on Nov. 20, 2023, which application claims the benefit of the following provisionally filed U.S. Patent Application No. 63/532,452, filed on Aug. 14, 2023, and entitled “Semiconductor Device and Method of Manufacturing the Same,” which applications are hereby incorporated herein by reference.

### BACKGROUND

Integrated circuit packages may have a plurality of package components such as device dies and package substrates bonded together to increase the functionality and integration level. Due to the differences between different materials of the plurality of package components, warpage may occur. The warpage may cause non-bond issues, and some conductive features that are intended to be bonded to each other are not bonded, resulting in circuit failure.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-13 illustrate the cross-sectional views of intermediate stages in the formation of a multi-tier package in accordance with some embodiments.

FIGS. 14-19 illustrate the cross-sectional views of intermediate stages in the formation of a multi-tier package in accordance with alternative embodiments.

FIGS. 20-23 illustrate the patterns and positions of stress modulation regions in wafers in accordance with some embodiments.

FIGS. 24A and 24B illustrate a vertical stress dopant distribution profile and a horizontal stress dopant distribution profile, respectively, in accordance with some embodiments.

FIG. 25 illustrates a process flow for forming a package including a stress modulation dopant in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A method of implanting stress modulation dopants into dielectric layers to form stress modulation regions is provided. The warpage profile of the implanted wafers may be improved, and the warpage may be reduced. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

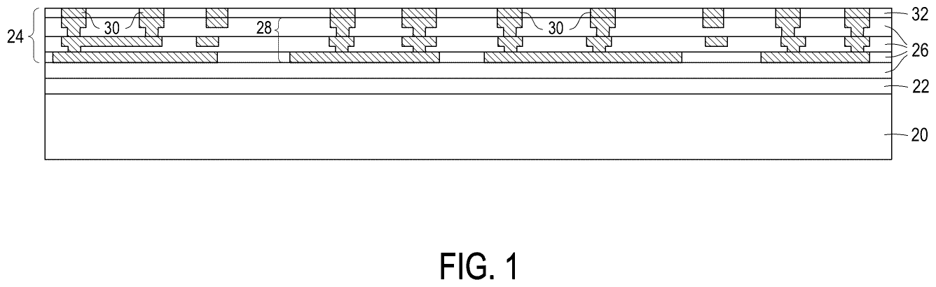

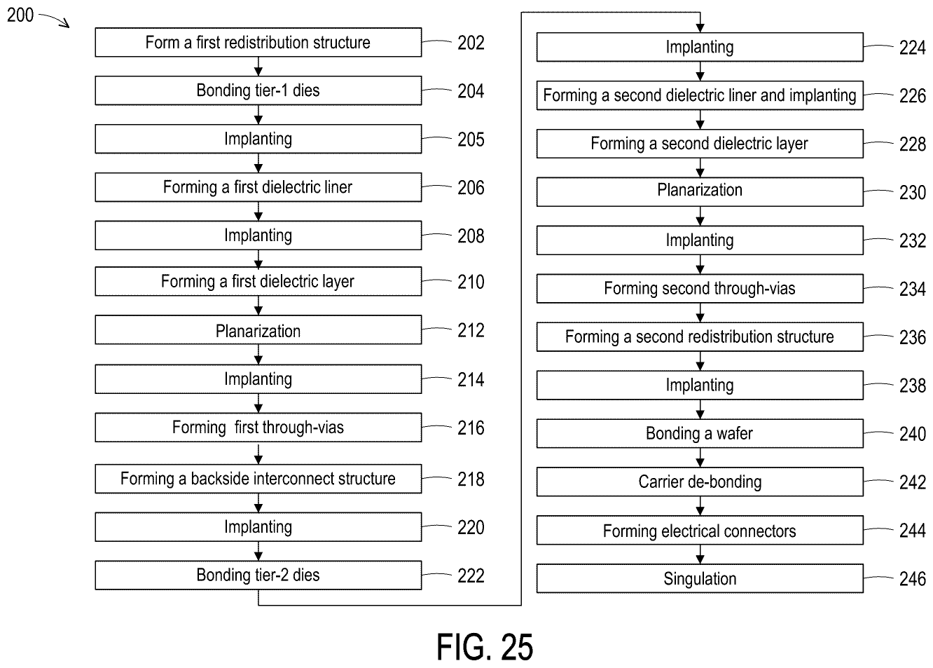

FIGS. 1 through 13 illustrate the cross-sectional views of intermediate stages in the formation of a package in accordance with some embodiments of the present disclosure. The corresponding processes are also reflected schematically in the process flow shown in FIG. 25.

FIG. 1 illustrates the formation of release film 22 on carrier 20. Carrier 20 may be a glass carrier, a silicon wafer, organic carrier, or the like. Release film 22 may be formed of a polymer-based material and/or an epoxy-based thermal-release material (such as a Light-To-Heat-Conversion (LTHC) material), which is capable of being decomposed under radiation such as a laser beam, so that carrier 20 may be de-bonded from the overlying structures that will be formed in subsequent processes. In accordance with some embodiments, release film 22 is applied on carrier 20 through coating.

FIG. 1 further illustrates the formation of a redistribution structure including Redistribution lines (RDLs) through an RDL-first process. The respective process is illustrated as process 202 in the process flow 200 as shown in FIG. 25. In accordance with alternative embodiments, the redistribution structure may be formed through an RDL-last process. A redistribution structure 24, which includes a plurality of dielectric layers 26 and a plurality of RDLs 28, is formed over the release film 22.

In accordance with some embodiments, dielectric layers 26 may be formed of or comprise inorganic dielectric materials, which may be silicon-containing dielectric materials such as SiO, SiC, SiN, SiON, SiOC, SiCN, SiOCN, or the like, or combinations thereof. In accordance with alternative embodiments, dielectric layers 26 may be formed of or comprise organic dielectric materials, which may be polymers. For example, dielectric layers 26 may be formed of or comprises polybenzoxazole (PBO), polyimide, benzocyclobutene (BCB), or the like.

In an example embodiment, the formation of a bottom layer of RDLs 28 may include forming a metal seed layer (not shown) over the underlying dielectric layer 26, forming a patterned mask (not shown) such as a photoresist over the metal seed layer, and then performing a metal plating process to deposit a metallic material on the exposed metal seed layer. The patterned mask and the portions of the metal seed layer covered by the patterned mask are then removed, leaving the bottom RDLs 28 as shown in FIG. 1. In accordance with some embodiments, the metal seed layer includes a titanium layer and a copper layer over the titanium layer. The metal seed layer may be formed using, for example, Physical Vapor Deposition (PVD) or a like process. The plating may be performed using, for example, an electrochemical plating process.

The formation of overlying RDLs 28 may include depositing a dielectric layer 26 over the bottom RDLs 28, patterning the dielectric layer 26 to form via openings and exposing the underlying RDLs 28, depositing a blanket metal seed layer extending into the via openings, and forming and patterning a plating mask (such as a photoresist), with openings formed in the plating mask and directly over the via openings. A plating process is then performed to plate a metallic material, which fills the via openings, and has some portions higher than the top surface of the dielectric layer 26. The plating mask is then removed, followed by an etching process to remove the exposed portions of the metal seed layer, which was previously covered by the plating mask. The remaining portions of the metal seed layer and the plated metallic material are RDLs 28. RDLs 28 include RDL lines (also referred to as traces or trace portions) and via portions (also referred to as vias). The trace portions are over the respective dielectric layer 26, and the via portions are in the respective dielectric layer 26.

Bond layer 32 and bond pads 30 are formed as a top portion of redistribution structure 24. Bond layer 32 may be formed of a silicon-containing dielectric material, which silicon-containing dielectric material may be selected from SiO, SiC, SiN, SiON, SiOC, SiCN, SiOCN, or the like, or combinations thereof. Bond pads 30 may comprise copper, and may be formed through a damascene process. The bond layer 32 and bond pads 30 are planarized so that their top surfaces are coplanar, which may be resulted due to a Chemical Mechanical Polish (CMP) process performed in the formation of bond pads 30.

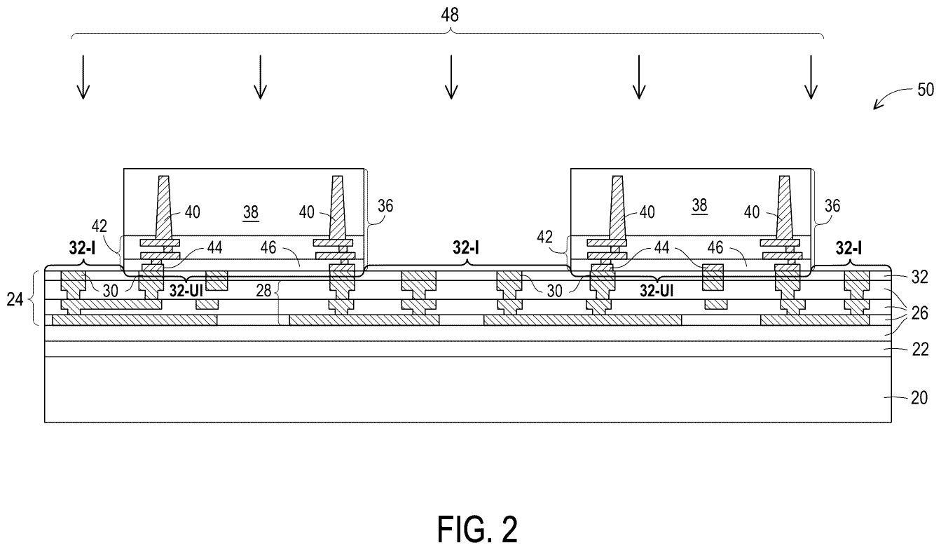

Referring to FIG. 2, device dies 36 are bonded to wafer 2. The respective process is illustrated as process 204 in the process flow 200 as shown in FIG. 25. In accordance with some embodiments, each of device dies 36 may be a logic die, which may be a Central Processing Unit (CPU) die, a microcontroller (MCU) die, an input-output (IO) die, a BaseBand die, or the like. Device dies 36 may also include memory dies.

Device dies 36 may include semiconductor substrates 38, which may be silicon substrates. Through-Silicon Vias (TSVs) 40, sometimes referred to as through-substrate vias, through-semiconductor vias or through-vias, are formed to extend into semiconductor substrates 38. TSVs 40 are used to connect the devices and metal lines formed on the front side (the illustrated bottom side) of semiconductor substrates 38 to the backside. Also, device dies 36 include interconnect structures 42 for connecting to the active devices and passive devices in device dies 36. Interconnect structures 42 include metal lines and vias.

Each of devices dies 36 includes bond pads 44 and bond layer 46 (also referred to as a bond film) at the illustrated bottom surface of device die 36. The bottom surfaces of bond pads 44 may be coplanar with the bottom surface of bond layer 46. In accordance with some embodiments, Bond layer 46 may be formed of a silicon-containing dielectric material, which may be selected from SiO, SiC, SiN, SiON, SiOC, SiCN, SiOCN, or the like, or combinations thereof. Bond pads 44 may comprise copper, and may be formed through a damascene process. The bond layer 46 and bond pads 44 are planarized so that their surfaces are coplanar, which may be resulted due to the CMP in the formation of bond pads 44.

The bonding may be achieved through bump-less stacked technologies, wafer-to-wafer bonding, die-to-wafer bonding or die-to-die bonding technologies. For example, bond pads 44 are bonded to bond pads 30 through metal-to-metal direct bonding. In accordance with some embodiments, the metal-to-metal direct bonding is copper-to-copper direct bonding. Furthermore, bond layers 46 are bonded to bond layer 32 through fusion bonding, for example, with Si—O—Si bonds being generated. The structure illustrated in FIG. 2 is referred to as reconstructed wafer 50 hereinafter, and more features will be formed to further expand the reconstructed wafer 50 in subsequent processes.

FIG. 2 illustrates an implantation process 48 to form stress modulation regions in bond layer 32 in accordance with some embodiments. The respective process is illustrated as process 205 in the process flow 200 as shown in FIG. 25. Throughout the description, a plurality of implantation processes are discussed. It does not mean that all of the discussed implantation processes are performed. Rather, the formation of the package may include one or more of the discussed implantation processes, while other discussed implantation processes may be skipped. At least one, or more, or all of the discussed implantation processes will be performed in any combination.

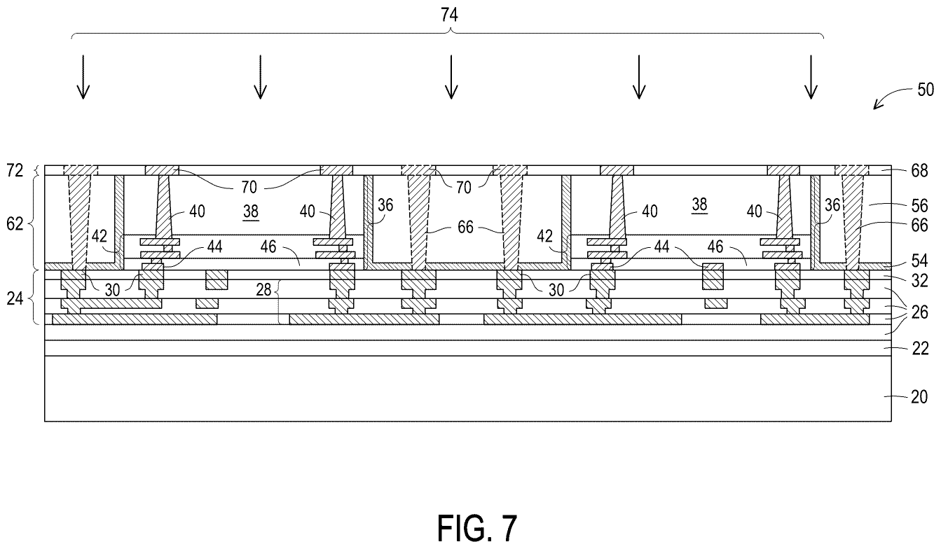

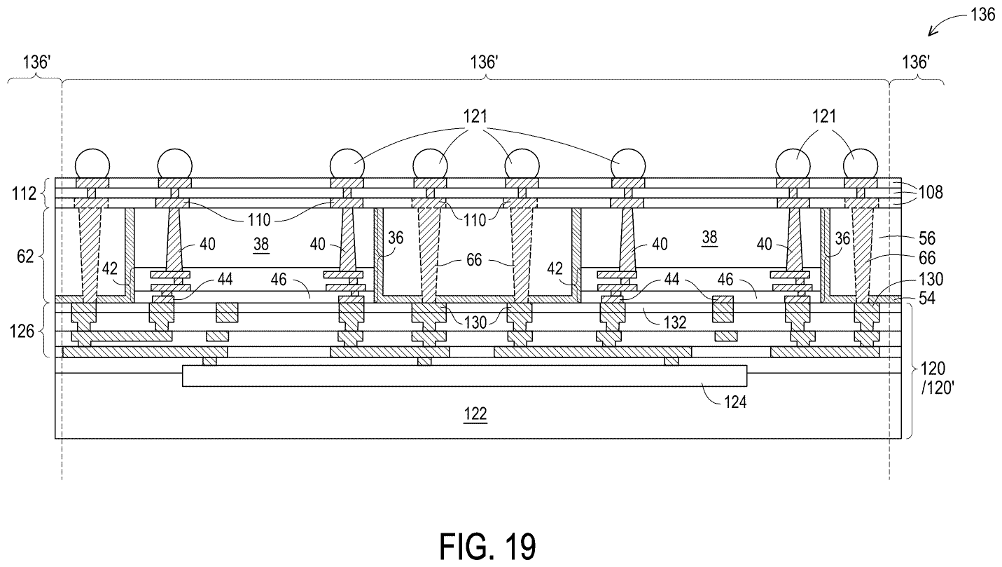

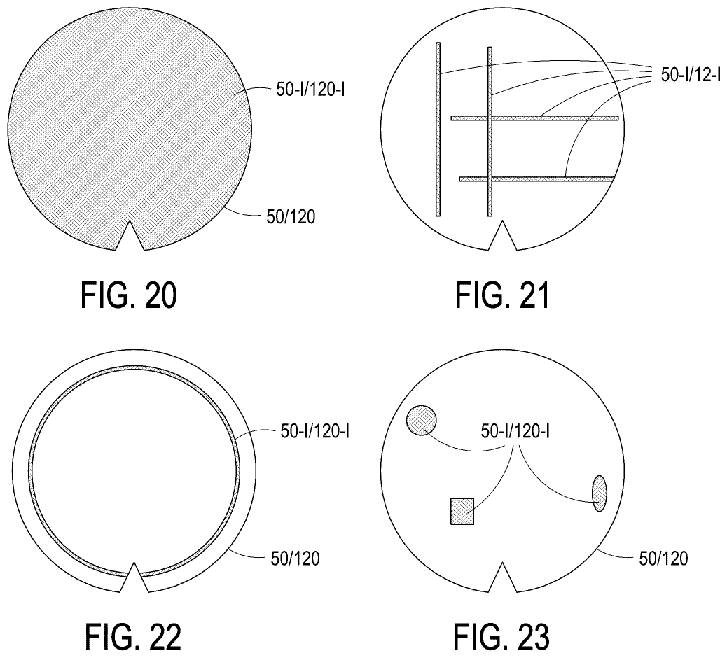

Before the implantation process 48 is performed, the parts of bond layer 32 to be implanted is determined. Either the entirety or some parts of the illustrated wafer-level structure may be implanted. For example, FIGS. 20 through 23 illustrate the parts to be implanted (as will be discussed in subsequent paragraphs) in the discussed implantation processes. In accordance with some embodiments, to determine which parts of the reconstructed wafer 50 is to be implanted, a sample reconstructed wafer may be formed, for example, as having a same structure as shown in FIG. 7 or 19. The warpage of the sample reconstructed wafer is measured. The measurement results include the warpage profile of the sample structure, such as which parts have warpage, and the degree of the warpage.

Based on the warpage profile, the parts of the reconstructed wafer 50 to be implanted are determined. In accordance with some embodiments, a blanket implantation is performed. In accordance with alternative embodiments, a selective implantation process is performed on some, but not all, of the reconstructed wafer 50. When the selective implantation process is performed, an implantation mask such as a patterned photoresist may be formed to mask the parts of the reconstructed wafer 50 that will not be implanted.

In accordance with some embodiments, the implanted ions (also referred to as stress modulation dopants hereinafter) may include Ge, B, P, As, Ga, or the like, or combinations thereof. The implanted ions may also include H, Y, Zr, Xe, In, Sb, Si, N, O, C, F, Ne, He, Ar, Kr, Cl, S, Se, Sn, Al, In, Er, Yb, or a combination thereof, and/or the combination with Ge, B, P, As, and/or Ga.

In accordance with some embodiments, the implantation process 48 is controlled, so that the peak concentration of the implanted stress modulation dopant is inside bond layer 32. Throughout the description, when a layer is discussed as being implanted with a stress modulation dopant, the implantation process is controlled, so that the peak concentration of the stress modulation dopant will be inside the implanted layer, and the concentration will reduce going into neighboring layers. In accordance with some embodiments, the peak concentration of the stress modulation dopant in the implanted layer may be greater than about 10¹⁶/cm³, and may be in the range between about 10¹⁶/cm³ and about 10²²/cm³ in accordance with some embodiments.

Throughout the description, the regions implanted with the stress modulation dopant are denoted as using letter “I” (to represent “Implanted”), and the implanted portions of bond layer 32 are denoted as implanted portions (or region) 32-I. The regions not implanted with the stress modulation dopant are denoted using symbol “UI” (to represent “Un-Implanted”) and hence the un-implanted portions of bond layer 32 are denoted as portions (or regions) 32-UI. The un-implanted regions (portions) may have a lower concentration of the stress modulation dopant than the implanted regions, or may be free from the stress modulation dopant.

As shown in FIG. 2, device dies 36 act as an implantation mask to mask the underlying portions of bond layer 32, so that these portions are un-implanted portions 32-UI. Some other portions are not covered by device dies 36, and are implanted to form implanted portions 32-I.

Through the implantation process 48, the material of bond layer 32 is modified. Furthermore, the density of the implanted portions is increased. The warpage of reconstructed wafer 50 is thus reduced, and the warpage profile is also modified. For example, implantation process 48 and/or the subsequently performed implantation processes individually or collectively may result in a warpage profile to be modified, and the warpage to be reduced.

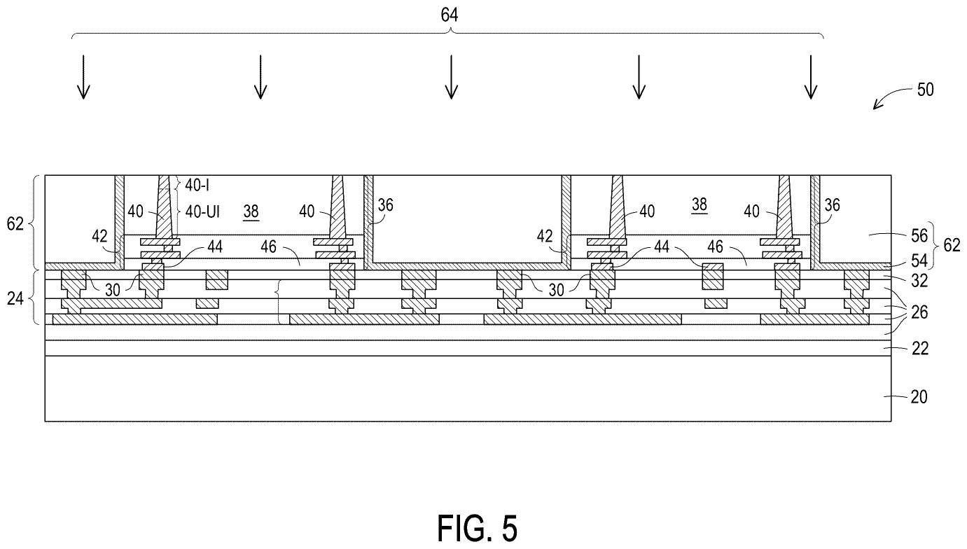

In accordance with some embodiments, a backside grinding process may be performed to thin device dies 36. Through the thinning of device dies 36, the aspect ratio of the gaps between neighboring device dies 36 is reduced in order to perform gap filling. Otherwise, the gap filling may be difficult due to the otherwise high aspect ratio of the gaps. After the backside grinding, TSVs 40 may be revealed. Alternatively, TSVs 40 are not revealed at this time, and the backside grinding is stopped when there is a thin layer of substrate covering TSVs 40. In accordance with these embodiments, TSVs 40 may be revealed in the step shown in FIG. 5.

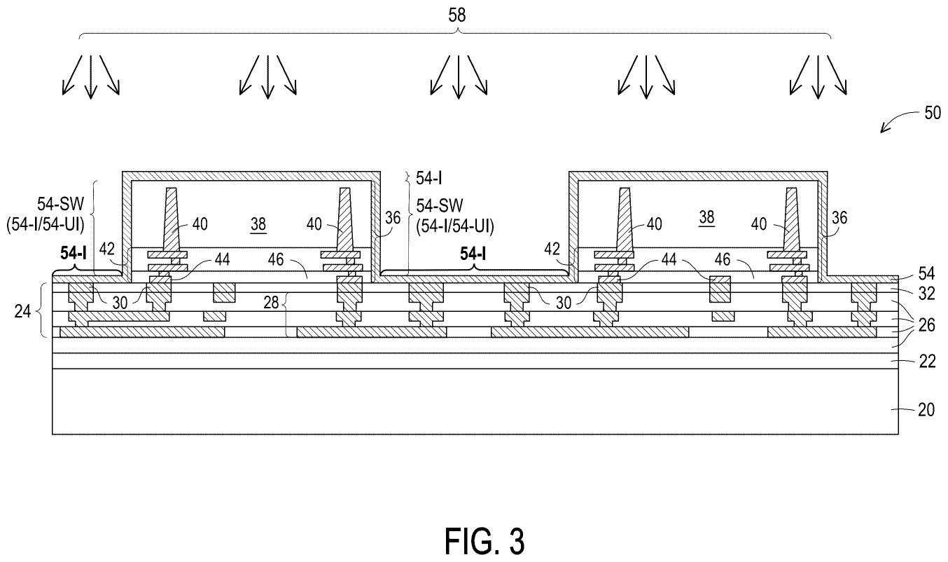

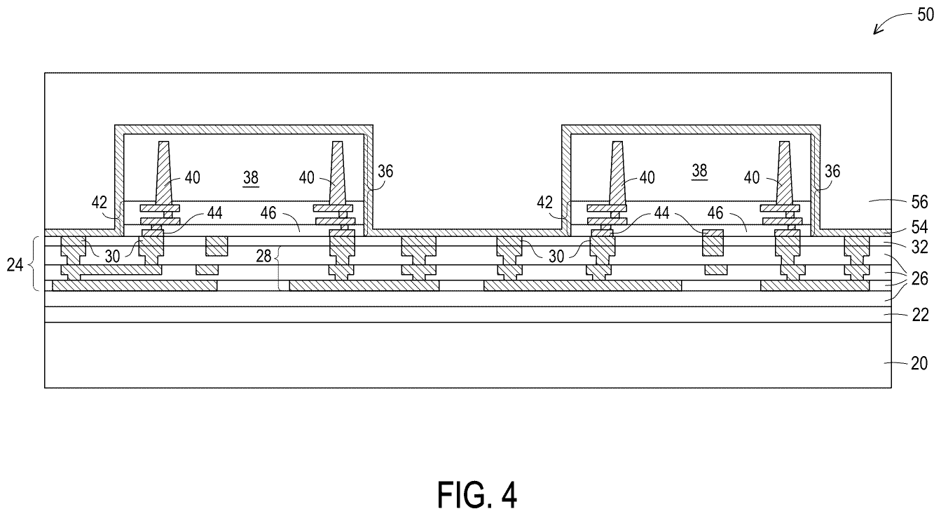

FIGS. 3 and 4 illustrate the formation of a plurality of gap-filling layers. In accordance with some embodiments, the gap-filling layers includes dielectric liner 54, and dielectric layer 56 over and contacting dielectric liner 54.

Referring to FIG. 3, dielectric liner 54 is deposited. The respective process is illustrated as process 206 in the process flow 200 as shown in FIG. 25. Dielectric liner 54 may be deposited using conformal deposition methods such as Atomic Layer Deposition (ALD) or Chemical Vapor Deposition (CVD). Dielectric liner 54 is formed of a dielectric material that has good adhesion to the sidewalls of device dies 36 and the top surfaces of bond layer 32 and bond pads 30. In accordance with some embodiments, dielectric liner 54 is formed of a nitride-containing material such as silicon nitride, SiON, SiCN, or the like. Dielectric liner 54 extends on, and contacts, the sidewalls of device dies 36.

In accordance with some embodiments, implantation process 58 is performed to implant a stress modulation dopant into dielectric liner 54. The respective process is illustrated as process 208 in the process flow 200 as shown in FIG. 25. In accordance with alternative embodiments, the implantation process 58 is skipped. In accordance with some embodiments, implantation process 58 includes tilt implantations, so that the stress modulation dopant may be implanted into the sidewall portions 54-SW of the dielectric liner 54, which sidewall portions are on the sidewalls of device dies 36. The sidewall portions 54-SW are thus also denoted as 54-I in accordance with some embodiment. The implantation process conditions, such as the tilt angle and the implantation energy, are controlled so that the peak concentration of the stress modulation dopant is in the sidewall portions of dielectric liner 54. The peak concentrations of the stress modulation dopant may also be in the horizontal portions of dielectric liner 54, or may be in the underlying bond layer 32 in accordance with some embodiments, depending on the implantation energy and the tilt angle.

The implantation process 58 may also include a vertical implantation process, which may be formed in addition to the tilt implantation, or may be performed without performing the tilt implantation. The vertical implantation process is controlled to have the peak concentration of the stress modulation dopant in the horizontal portions of the dielectric liner 54.

When the implantation process 58 includes the vertical implantation process, but does not include the tilt implantation, the lower portions of the sidewall portions 54-SW may be free from the stress modulation dopant, and are also denoted as 54-UI in accordance with alternative embodiments, while the horizontal portions and some upper parts of the sidewall portions are doped, and are marked as 54-I.

The stress modulation dopant introduced by the implantation process 58 may be selected from the same group of candidate dopants of the implantation process 48 (FIG. 2), and may be the same as or different from the stress modulation dopant introduced by the implantation process 48.

FIG. 4 illustrates the formation of dielectric layer 56 over and contacting dielectric liner 54. The respective process is illustrated as process 210 in the process flow 200 as shown in FIG. 25. Dielectric layer 56 is formed of a material different from the material of dielectric liner 54. In accordance with some embodiments, dielectric layer 56 is formed of silicon oxide, while other dielectric materials such as silicon carbide, silicon oxynitride, silicon oxy-carbo-nitride, or the like may also be used when there is an adequate etching selectivity (for example, higher than about 50) between dielectric layer 56 and dielectric liner 54. The etching electivity is the ratio of the etching rate of dielectric layer 56 to the etching rate of dielectric liner 54 when etching dielectric layer 56 in a subsequent process. Dielectric layer 56 may be deposited as a conformal layer, with the thicknesses of the horizontal portions and vertical portions being substantially equal to each other, or as a non-conformal dielectric layer.

Referring to FIG. 5, a planarization process such as a CMP process or a mechanical grinding process is performed to remove excess portions of dielectric layer 56 and dielectric liner 54, so that device dies 36 are exposed. The respective process is illustrated as process 212 in the process flow 200 as shown in FIG. 25. Also, through-vias 40 are exposed. The remaining portions of dielectric liner 54 and dielectric layer 56 are collectively referred to as (gap-filling) isolation regions 62.

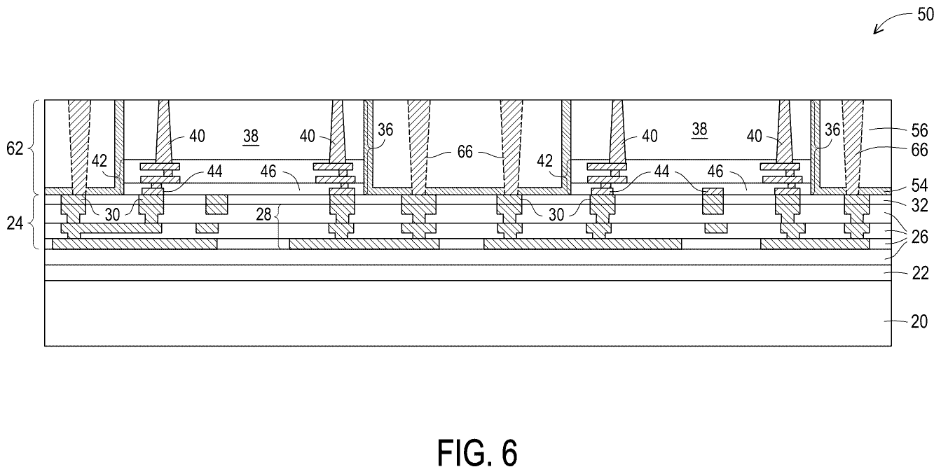

In accordance with some embodiments, implantation process 64 is performed to implant a stress modulation dopant into isolation regions 62. The respective process is illustrated as process 214 in the process flow 200 as shown in FIG. 25. In accordance with alternative embodiments, the implantation process 64 is skipped. In accordance with yet alternative embodiments, the implantation process 64 is performed after the formation of through-vias 66 as shown in FIG. 6. The peak concentrations of the stress modulation dopant may be inside isolation regions 62, and may also be in semiconductor substrate 38.

In the implantation process 64, semiconductor substrates 38 and some top portions of through-vias 40 are also implanted. Since the density of through-vias 40 (which comprise metal) is high, the stress modulation dopant is concentrated at the top portions of through-vias 40. For example, FIG. 5 schematically illustrates the top portions 40-I incorporating the stress modulation dopant, and the lower portions 40-UI free from the stress modulation dopant. Due to the blocking of through-vias 40, the stress modulation dopant is rich at the top surface portions 40-I of through-vias 40, with a concentration of the stress modulation dopant in the top portions 40-I being higher that in the dielectric liner 54 and dielectric region 56.

In accordance with some embodiments, the peak concentration of stress modulation dopant is at, or higher than, a middle level of isolation regions 62, which middle level is between the top surface and the bottom surface of isolation regions 62. The stress modulation dopant introduced by the implantation process 64 may extend to the bottom of isolation regions 62, or may be limited to an upper portion of isolation regions 62, with the bottom portions of isolation regions 62 free from the stress modulation dopant.

The stress modulation dopant introduced by the implantation process 64 may be selected from the same group of candidate dopants of, and may be the same as or different from, the stress modulation dopant introduced by the implantation process 48 and/or implantation process 58.

FIG. 6 illustrates the formation of through-vias 66, which penetrate through isolation regions 62. The respective process is illustrated as process 216 in the process flow 200 as shown in FIG. 25. In accordance with some embodiments, a patterned etching mask (not shown) such as a photoresist is formed, and dielectric layer 56 is etched using the patterned photoresist as an etching mask. Openings (occupied by through-vias 66) are thus formed, and extend down to dielectric liner 54, which acts as an etch stop layer. Another etching process is then performed to etch-through dielectric liner 54, exposing the underlying metal pads, which are also marked using reference numerals 30.

Next, a dielectric liner (not shown) is formed lining the sidewalls of the opening, so that the semiconductor substrates 38 are isolated from the subsequently formed through-vias 66. In a subsequent process, a conductive material is filled into the openings, followed by a planarization process to remove excess portions of the conductive material, forming through-vias 66.

In accordance with alternative embodiments, through-vias 66 are not formed. Accordingly, through-vias 66 are illustrated as being dashed to indicate that through-vias 66 may be or may not be formed.

Referring to FIG. 7, a (backside) interconnect structure 72 is formed on the backside of device dies 36. The respective process is illustrated as process 218 in the process flow 200 as shown in FIG. 25. Interconnect structure 72 includes redistribution lines (RDLs) 70 (which also include bond pads) and dielectric layer(s) 68 (which also include a bond layer). In accordance with some embodiments, dielectric layer 68 is formed of an oxide such as silicon oxide, a nitride such as silicon nitride, or the like. RDLs 70 may be formed using a damascene process, which includes etching dielectric layer 68 to form openings, depositing a conductive barrier layer into the openings, plating a metallic material such as copper or a copper alloy, and performing a planarization process to remove excess portions of RDLs 70.

In accordance with some embodiments, implantation process 74 is performed to implant a stress modulation dopant into dielectric layer 68. The respective process is illustrated as process 220 in the process flow 200 as shown in FIG. 25. In accordance with alternative embodiments, the implantation process 74 is skipped. The peak concentrations of the stress modulation dopant may be inside dielectric layer 68. The stress modulation dopant introduced by the implantation process 74 may be selected from the same group of candidate dopants of the implantation processes 48 (FIG. 2), implantation process 58 (FIG. 3), and/or implantation process 64 (FIG. 5).

In accordance with some embodiments, the packaging process includes a multi-tier packaging process, wherein device dies 36 are tier-1 dies. In subsequent processes, tier-2 dies are bonded. The processes for forming the tier-2 dies may be similar to the processes related to the tier-1 dies, and are discussed briefly hereinafter.

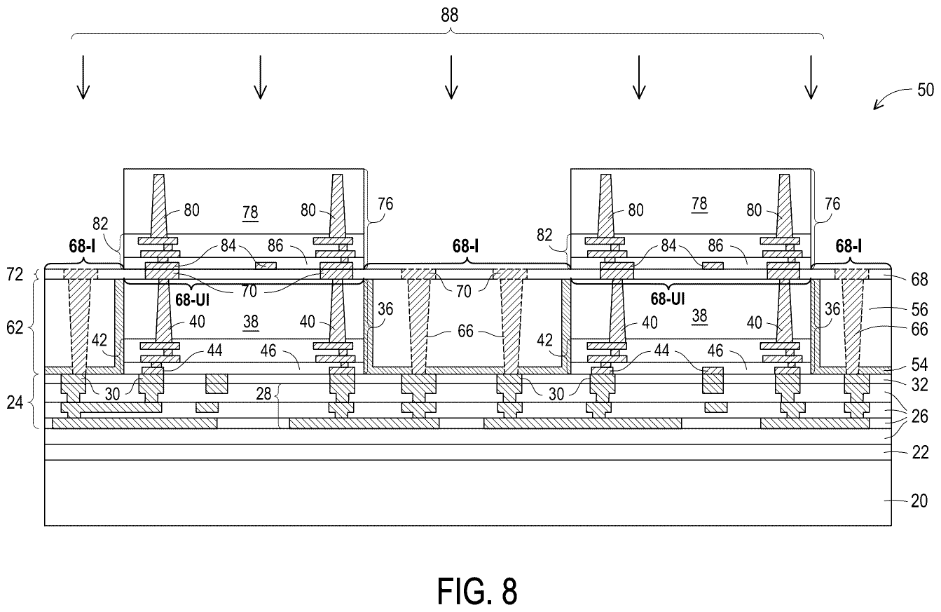

Referring to FIG. 8, device dies 76 (tier-2 dies) are bonded to the bond pads in the interconnect structure 72. The respective process is illustrated as process 222 in the process flow 200 as shown in FIG. 25. Device dies 76 may include semiconductor substrates 78, through-vias 80, interconnect structures 82, bond pads 84, and bond layers 86. In some embodiments, the bond pads 84 is bonded to the bond pads in RDLs 70 through metal-to-metal direct bonding, and bond layer 86 is bonded to the bond layer in dielectric layers 68 through fusion bonding.

In accordance with some embodiments, implantation process 88 is performed to implant a stress modulation dopant into selected portions of dielectric layer 68, which portions are not covered by device dies 76, and are referred to as stress modulation regions 68-I. The respective process is illustrated as process 224 in the process flow 200 as shown in FIG. 25. In accordance with alternative embodiments, the implantation process 88 is skipped. The portions of dielectric layer 68 directly underlying device dies 76 are un-implanted, and are referred to as un-implanted portions 68-UI. The peak concentrations of the stress modulation dopant may be inside dielectric layer 68. The stress modulation dopant introduced by the implantation process 88 may be selected from the same group of, and may be the same as or different from, the stress modulation dopant introduced by implantation processes 48, 58, 64, and/or 74.

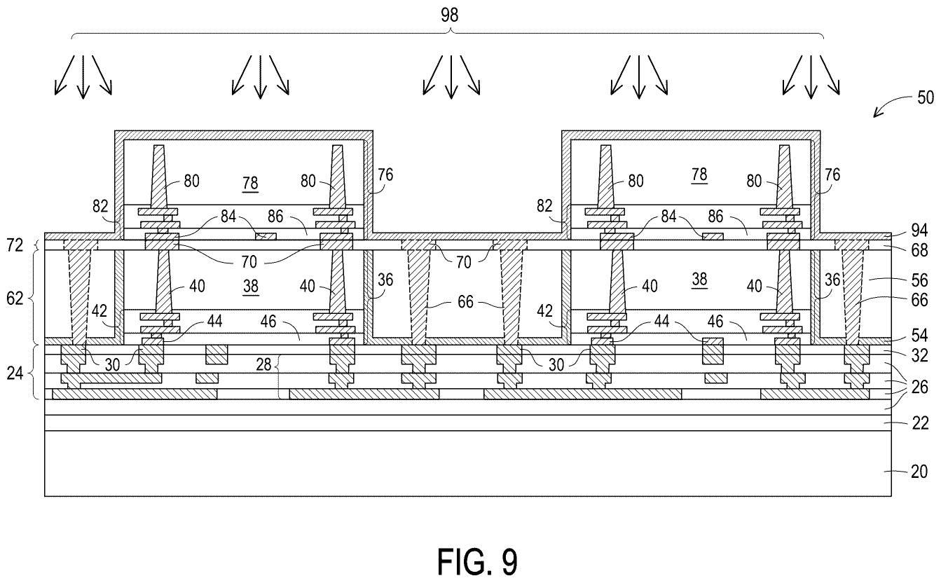

FIG. 9 illustrates the formation of dielectric liner 94, and the optional implantation process 98 in accordance with some embodiments. The respective process is illustrated as process 226 in the process flow 200 as shown in FIG. 25. The details of dielectric liner 94 and implantation process 98 may be essentially the same as that of dielectric liner 54 and implantation process 58 as shown in FIG. 3, and the details are not repeated herein.

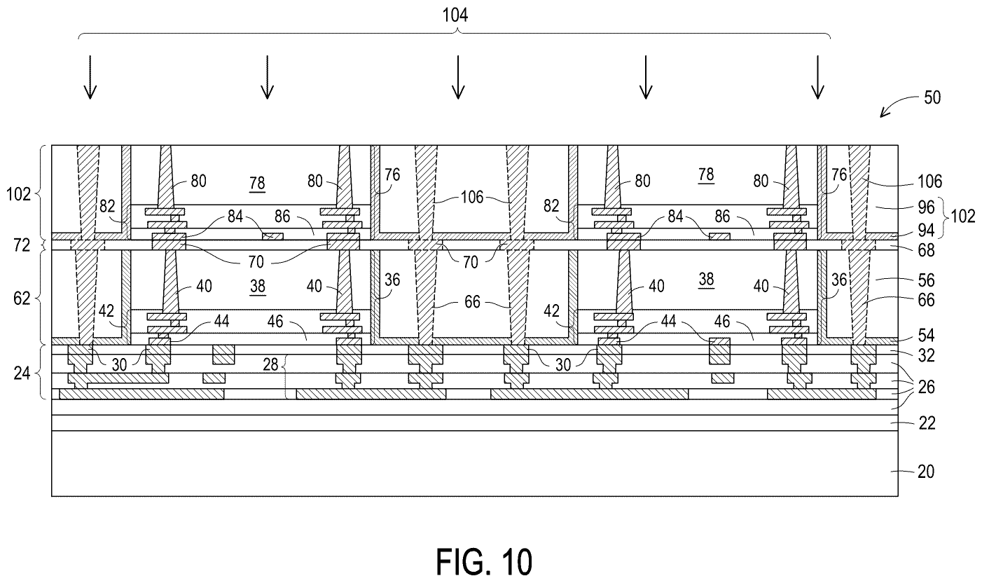

FIG. 10 illustrates the formation of dielectric layer 96, the planarization process to form isolation regions 102, and the optional formation of through-vias 106. The respective process is illustrated as processes 228, 230, 232, and 234 in the process flow 200 as shown in FIG. 25. An optional implantation process 104 may be (or may not be) performed. The details of dielectric layer 96, through-vias 106, and implantation process 104 may be essentially the same as that of dielectric layer 56, through-vias 66, and implantation process 64 as shown in FIGS. 4-6, and the details are not repeated herein.

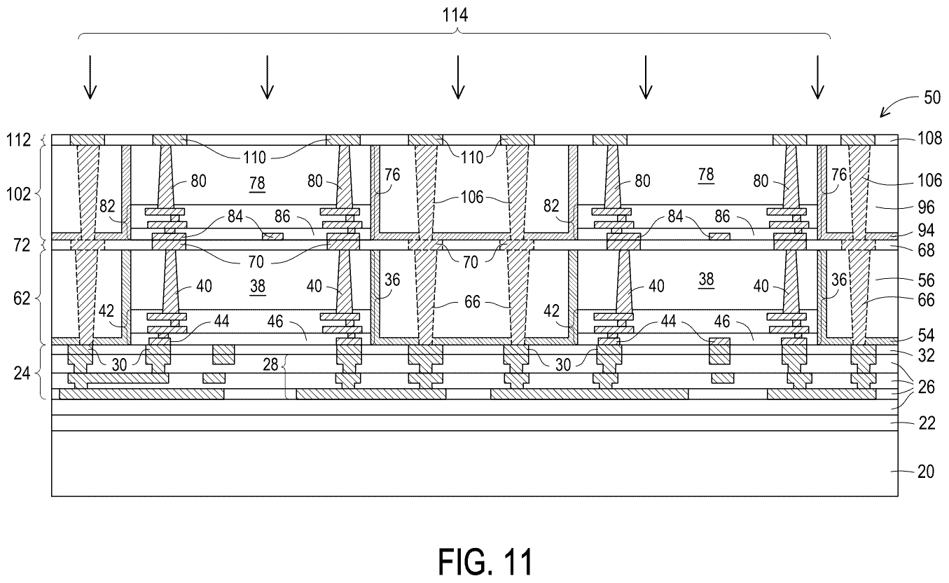

FIG. 11 illustrates the formation of redistribution structure 112, which include dielectric layer(s) 108 and RDLs 110, and the optional implantation process 114 in accordance with some embodiments. The respective process is illustrated as processes 236 and 238 in the process flow 200 as shown in FIG. 25. The details of dielectric layers 108, RDLs 110, and the implantation process 114 may be essentially the same as that of dielectric layers 68, RDLs 70, and the implantation process 74 as shown in FIG. 7, and the details are not repeated herein. The formation of reconstructed wafer 50 is thus finished.

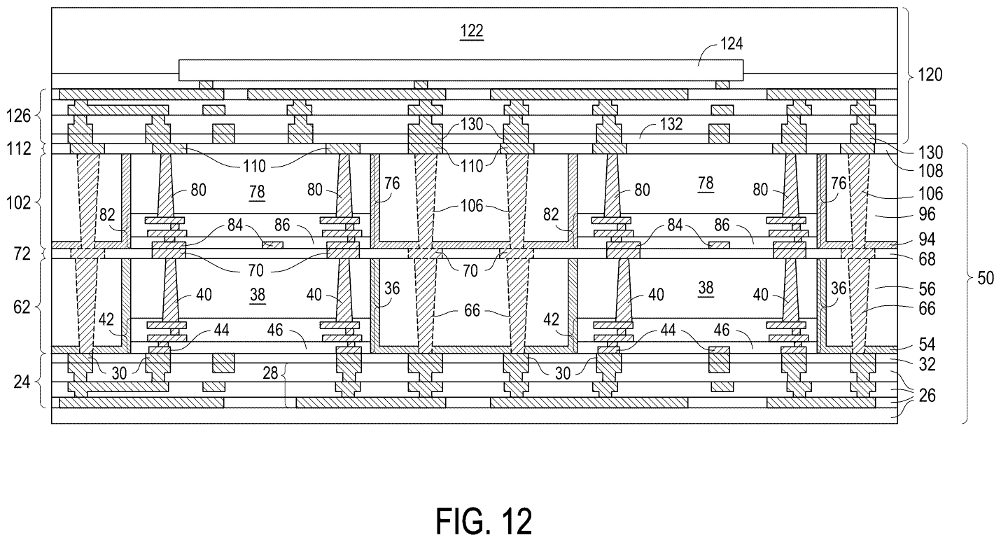

In a subsequent process, as shown in FIG. 12, wafer 120 is bonded to the reconstructed wafer 50 through a wafer-on-wafer bonding process. The respective process is illustrated as process 240 in the process flow 200 as shown in FIG. 25. In accordance with alternative embodiments, more tiers of device dies may be further bonded to tier-2 device dies 76 to further extend reconstructed wafer 50 before the bonding of wafer 120. Due to the implantation processes performed during the formation of reconstructed wafer 50, the warpage profile of reconstructed wafer 50 is improved, and/or the warpage of reconstructed wafer 50 is reduced. Accordingly, the bonding of wafer 120 and reconstructed wafer 50 may be free from non-bond issues.

In accordance with some embodiments, wafer 120 is a device wafer including semiconductor substrate 122, integrated circuit devices 124, interconnect structure 126, bon bond pads 130, and bond layer 132.

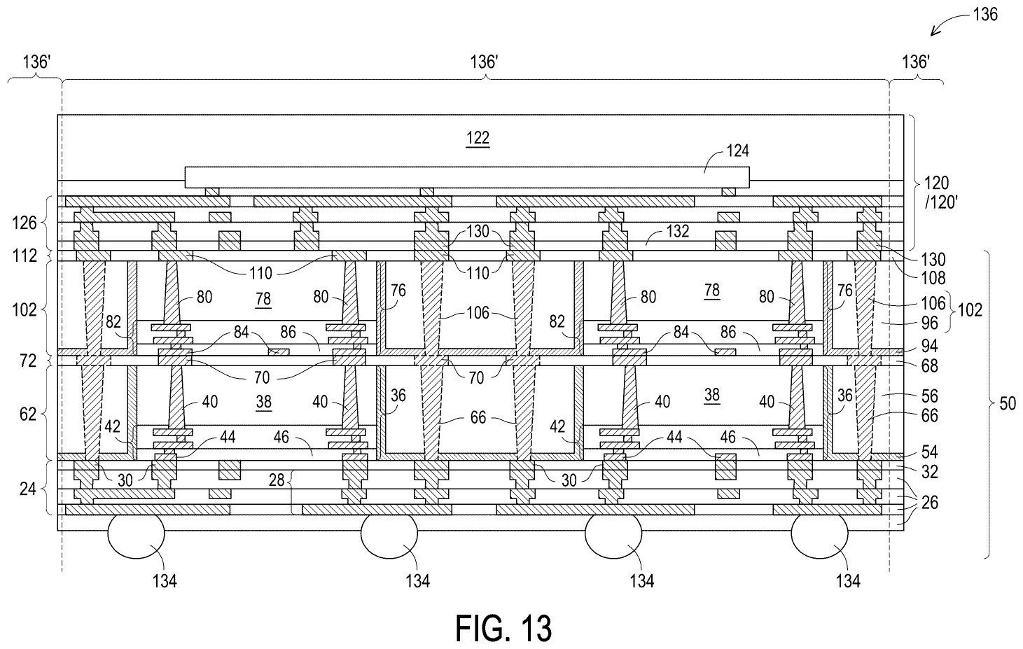

Next, reconstructed wafer 50 is de-bonding from carrier 20, for example, by projecting a laser beam onto LTHC coating material 22, so that LTHC coating material 22 is decomposed, releasing reconstructed wafer 50 from carrier 20. The respective process is illustrated as process 242 in the process flow 200 as shown in FIG. 25. The resulting structure is shown in FIG. 13. In subsequent processes, electrical connectors 134, which may be, for example, solder regions are formed to connect to the front-side redistribution structure 24, forming reconstructed wafer 136. The respective process is illustrated as process 244 in the process flow 200 as shown in FIG. 25. In accordance with alternative embodiments in which redistribution structure 24 has not been formed in the process as shown in FIG. 1, redistribution structure 24 may be formed after the de-bonding of carrier 20.

In subsequent processes, reconstructed wafer 136 is singulated in a sawing process, so that discrete packages 136′ are formed. The discrete packages 136′ include device dies 120′ sawed from device wafer 120, and also include device dies 36 and device dies 76. The respective process is illustrated as process 246 in the process flow 200 as shown in FIG. 25.

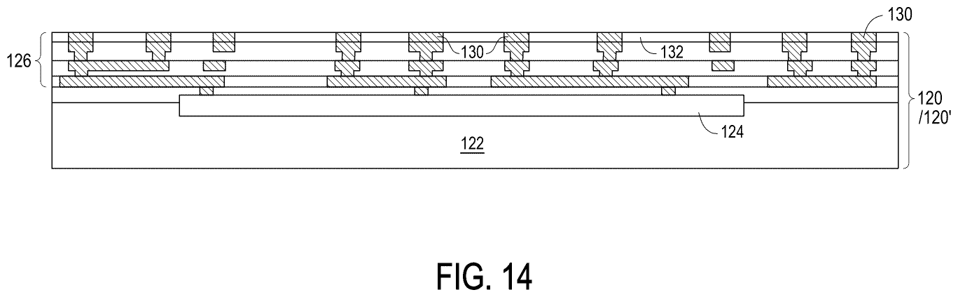

The above-discussed process illustrates a face-to-back bonding process, in which the face (front side) of device die 120′ faces the backside of device die 76. The front side of device die 76 also faces the backside of device die 36. FIGS. 14 through 19 illustrate the formation of a package in accordance with alternative embodiments, in which face-to-face bonding is performed. Unless specified otherwise, the materials, the structures, and the formation processes of the components in these embodiments are essentially the same as the like components denoted by like reference numerals in the preceding embodiments. The details regarding the materials, the structures, and the formation processes provided in each of the embodiments throughout the description may be applied to any other embodiment whenever applicable.

Referring to FIG. 14, device wafer 120 is formed. In accordance with some embodiments, wafer 120 is a device wafer including semiconductor substrate 122, integrated circuit devices 124, and interconnect structure 126. Interconnect structure 126 also include bond pads 130 and bond layer 132. Device wafer 120 further includes device dies 120′ therein.

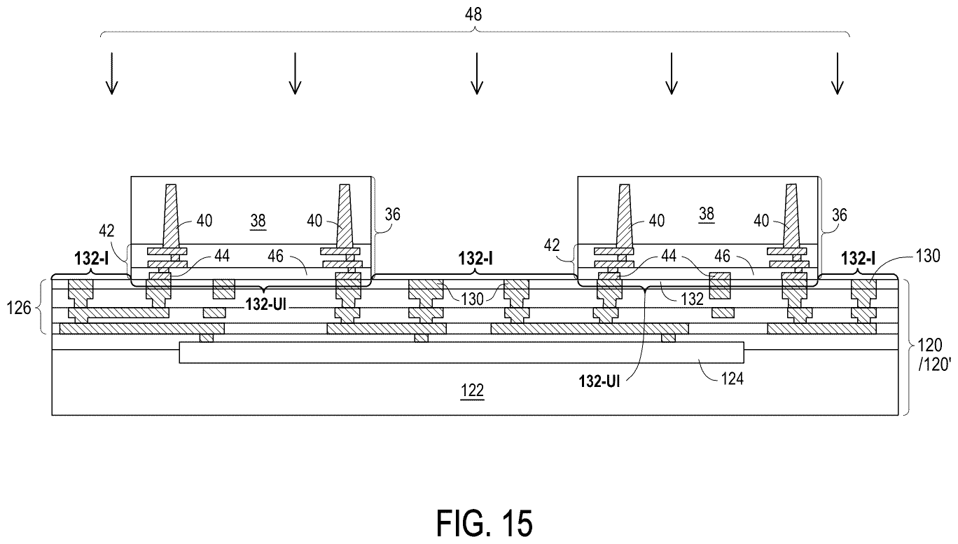

Referring to FIG. 15, device dies 36 are bonded to device wafer 120 through a die-on-wafer bonding process. Next, in accordance with some embodiments, implantation process 48 may be performed, or may not be performed. Implanted regions 132-I and un-implanted regions 132-UI are thus resulted.

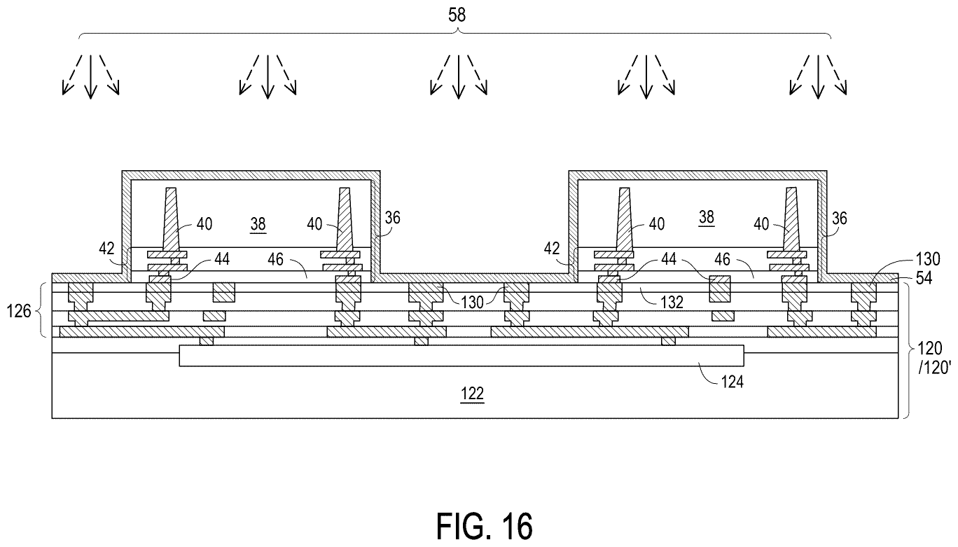

The details of the implantation processes in accordance with the processes in FIGS. 16 through 18 may be essentially the same as discussed referring to the embodiments in FIGS. 3 through 7. The processes are briefly mentioned hereinafter, and the details may be found referring to the preceding embodiments.

Referring to FIG. 16, dielectric liner 54 is deposited as a conformal layer through a conformation deposition process. In accordance with some embodiments, implantation process 58 may be performed, or may not be performed.

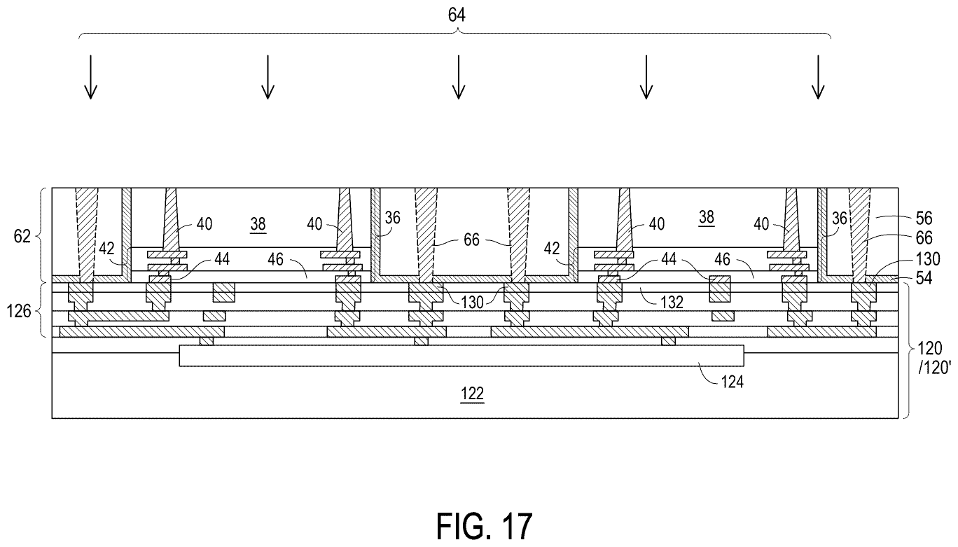

FIG. 17 illustrates the formation of dielectric layer 56, isolation regions 62, and optional through-vias 66 in accordance with some embodiments. Implantation process 64 may be performed or may be skipped. When implantation process 64 is performed, it is performed after the formation of isolation regions 62, and may be before or after the formation of through-vias 66.

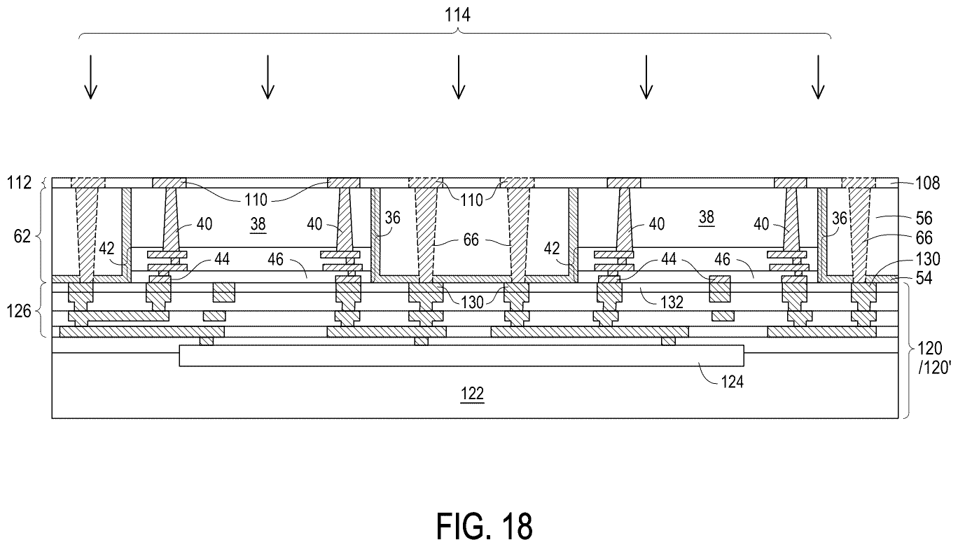

FIG. 18 illustrates the formation of a lower portion of redistribution structure 112 (FIG. 19), which includes dielectric layer 108 and redistribution lines 110 therein. Implantation process 114 may be performed or may be skipped.

FIG. 19 illustrates the further formation of redistribution structure 112, which includes more dielectric layer 108 and redistribution lines 110 therein. Electrical connectors 121 are then formed on redistribution lines 110. Electrical connectors 121 may include solder regions in accordance with some embodiments. Reconstructed wafer 136 is thus formed. In a subsequent process, a singulation process is performed to saw reconstructed wafer 136 into a plurality of discrete packages 136′.

In the discrete packages 136′ as shown in FIG. 13 or FIG. 19, the regions implanted with the stress modulation dopant may have a higher concentration DC-I of the stress modulation dopant(s) than the stress modulation dopant concentration DC-UI of un-doped portions of the packages. For example, the implanted regions may include regions 32-I, dielectric liner 54, dielectric region 56, dielectric layer 68-I, dielectric liner 94, and/or dielectric layer 108. Depending on which of the implantation processes are performed or skipped, at least one or more or all (in any combination) of these regions/layers may be implanted and have stress modulation dopant concentration DC-I. The un-implanted regions may include bond layer 46 of device dies 36, the bond layer 86 of device dies 76, the bond layer 132 of device die 120′, the un-implanted regions 32-UI and/or 68-I (when implantation process 74 is skipped), and the like. In accordance with some embodiments, the ratio DC-I/DC-UI may be greater than about 10, greater than about 100, or even greater. Concentration DC-UI may be equal to o (no stress modulation dopant) or greater than o/cm³.

FIGS. 20-23 illustrate the implanted portions in wafer 120 and reconstructed wafer 50 (referred to as wafer 120/50 hereinafter) in accordance with some embodiments. The corresponding implantation processes are discussed referring to the preceding embodiments, and may include one, more, or all of implantation processes 48, 58, 64, 74, 88, 98, 104, and 114 in any combination. As shown in FIG. 20, the entire wafer 50/120 is implanted, with the implanted portions denoted as 50-I/120-I.

In FIG. 21, some strip portions 50-I/120-I of wafer 50/120 are implanted, and the rest parts of wafer 50/120 are not implanted. The overlapped regions of the implanted strips 50-I/120-I having lengthwise directions in the X-direction and the implanted strips having lengthwise directions in the X-direction in the Y-direction may overlap the regions where the warpage value is highest among carrier wafer 50/120. FIG. 22 illustrates an embodiment in which the implanted region 50-I/120-I is a circular region, or may include a plurality of circular regions. FIG. 23 illustrates an embodiment in which selected and isolated regions 50-I/120-I are implanted.

Furthermore, the implanted portions of one of the implantation processes 48, 58, 64, 74, 88, 98, 104, and 114 may be the same as or different from the implanted regions of other implantation processes to achieve better results.

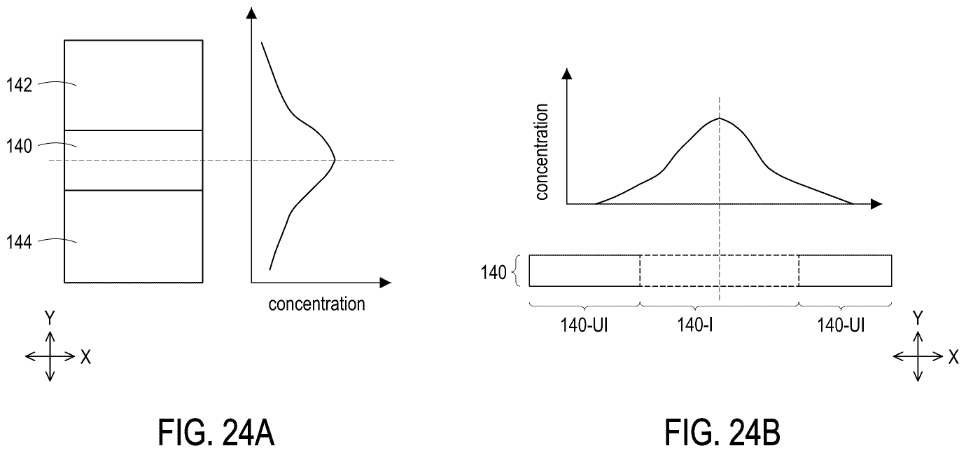

FIG. 24A illustrates a distribution profile of the stress modulation dopant in a stress modulation region/layer 140, which represents any of the above-discussed stress modulation layer/regions 32-I, 56, 68/68-I, 96, 108, and the like. The Y-direction in FIGS. 24A and 24B represents the direction perpendicular to the major surfaces of the implanted regions/layers. Accordingly, for all implanted regions/layer except the sidewall portions of the dielectric liners 54 and 94, the Y-direction in FIGS. 24A and 24B represent the vertical directions in FIGS. 19 and 19. For the implanted sidewall portions of the dielectric liners 54 and 94, the Y-direction in FIGS. 24A and 24B represents the horizontal directions in FIGS. 19 and 19.

In FIG. 24A, layer 142 and 144 represent the dielectric layers overlying (if any) and underlying the stress modulation region/layer 140. The concentrations of the stress modulation dopant are shown on the right side of the figure. In accordance with some embodiments, the peak concentration of the stress modulation dopant is in (and may be at or close to the middle level of) the stress modulation region/layer 140. In the directions away from where the peak concentration occurs, the concentrations of the stress modulation dopant may gradually reduce.

FIG. 24B illustrates a distribution profile of the stress modulation dopant in an implanted region 140-I (which may be implanted regions 32-I, 68-I, and/or 132-I) and un-implanted region 140-UI (which may be un-implanted region 32-UI, 68-UI, and/or 132-UI) in a dielectric layer 140. Dielectric layer 140 may represent any of the above-discussed selectively implanted stress modulation layer/regions. In accordance with some embodiments, the peak concentration of the stress modulation dopant is in (and may be at or close to the middle of) the implanted region 140-I. The concentrations of the stress modulation dopant may gradually reduce going into the neighboring un-implanted region 140-UI. Some portions of the un-implanted regions 140-UI may be free from the stress modulation dopant.

In above-illustrated embodiments, some processes and features are discussed in accordance with some embodiments of the present disclosure to form a three-dimensional (3D) package. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The embodiments of the present disclosure have some advantageous features. By forming stress modulation regions in dies and/or wafers through ion implantation processes, the warpage of the device dies and/or wafers may be reduced, and the warpage profiles may be modified. This may improve the bonding and reduce the non-bond issues. For example, when a top wafer and a bottom wafer have reduced warpage, and/or their warpage profiles are similar to each other, it is easier for the wafers to fit with each other and to improve the bonding.

In accordance with some embodiments, a method comprises bonding a first device die onto a package component, wherein the first device die comprises a semiconductor substrate; and a through-via extending into the semiconductor substrate; depositing a dielectric liner lining sidewalls of the first device die; depositing a dielectric layer on the dielectric liner; planarizing the dielectric layer and the first device die, wherein remaining portions of the dielectric liner and the dielectric layer form a gap-filling region, and a top end of the through-via is revealed; performing a first implantation process to introduce a stress modulation dopant into at least one of the dielectric liner and the dielectric layer; and forming a redistribution line over and electrically connecting to the through-via.

In an embodiment, the first implantation process is performed on the dielectric liner, and is performed before the dielectric layer is deposited. In an embodiment, the first implantation process comprises a tilt implantation process. In an embodiment, the first implantation process comprises a vertical implantation process. In an embodiment, the first implantation process is performed after the dielectric layer and the first device die are planarized. In an embodiment, the method further comprises, after the first device die is bonded to the package component and before the dielectric liner is deposited, performing a second implantation process to implant a top dielectric layer of the package component.

In an embodiment, the method further comprises bonding a second device die over the first device die; depositing an additional dielectric liner lining sidewalls of the second device die; depositing an additional dielectric layer on the additional dielectric liner; planarizing the additional dielectric layer and the second device die, wherein remaining portions of the additional dielectric liner and the additional dielectric layer form an additional gap-filling region; and performing a second implantation process to introduce an additional stress modulation dopant into at least one of the additional dielectric liner and the additional dielectric layer.

In an embodiment, the stress modulation dopant is same as the additional stress modulation dopant. In an embodiment, the first implantation process comprises implanting an element selected from the group consisting of Ge, B, P, As, Ga, H, Y, Zr, Xe, In, Sb, Si, N, O, C, F, Ne, He, Ar, Kr, Cl, S, Se, Sn, Al, In, Er, Yb, and combinations thereof. In an embodiment, the implanting the stress modulation dopant comprises implanting the element selected from the group consisting of Ge, B, P, As, Ga, and combinations thereof. In an embodiment, a peak concentration of the stress modulation dopant is in the dielectric liner.

In accordance with some embodiments, a structure comprises a package component comprising a top dielectric layer, wherein the top dielectric layer comprises a first portion; and a second portion; a device die over and bonding to the second portion of the top dielectric layer; and a gap-filling dielectric region comprising a dielectric liner comprising vertical portions lining sidewalls of the device die; and a horizontal portion over and contacting the first portion of the top dielectric layer, wherein the horizontal portion comprises a stress modulation dopant having a first concentration, and wherein a second concentration of the stress modulation dopant in the second portion of the top dielectric layer of the package component is lower than the first concentration; and a dielectric region on the dielectric liner.

In an embodiment, the device die comprises a bottom dielectric layer bonding to the second portion of the top dielectric layer, wherein the bottom dielectric layer is free from the stress modulation dopant therein. In an embodiment, the device die comprises a semiconductor substrate; and a through-via penetrating through the semiconductor substrate, wherein a third concentration of the stress modulation dopant in a top portion of the through-via is higher than both of the first concentration and the second concentration. In an embodiment, the stress modulation dopant comprises an element selected from the group consisting of Ge, B, P, As, Ga, H, Y, Zr, Xe, In, Sb, Si, N, O, C, F, Ne, He, Ar, Kr, Cl, S, Se, Sn, Al, In, Er, Yb, and combinations thereof. In an embodiment, the element is selected from the group consisting of Ge, B, P, As, Ga, and combinations thereof.

In accordance with some embodiments, a structure comprises a first device die; a second device die over and bonding to the first device die, wherein the first device die laterally extends beyond sidewalls of the second device die; and a gap-filling dielectric region comprising a dielectric liner comprising vertical portions on the sidewalls of the second device die; and a horizontal portion over and contacting the first device die to form a horizontal interface, wherein the horizontal portion comprises a stress modulation dopant therein, and the stress modulation dopant has a first peak concentration in the horizontal portion.

In an embodiment, concentrations of the stress modulation dopant gradually reduce from a location of the first peak concentration in an upward direction and a downward direction. In an embodiment, the vertical portions comprise the stress modulation dopant therein, and the stress modulation dopant has a second peak concentration in the vertical portions. In an embodiment, concentrations of the stress modulation dopant gradually reduce from a location of the second peak concentration in opposing horizontal directions.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
bonding a first device die onto a package component, wherein the first device die comprises a semiconductor substrate;
depositing a dielectric liner lining sidewalls of the first device die;
depositing a dielectric layer on the dielectric liner;
planarizing the dielectric layer and the first device die, wherein remaining portions of the dielectric liner and the dielectric layer form a gap-filling region;
performing a first implantation process to introduce a stress modulation dopant into at least one of the dielectric liner and the dielectric layer; and
forming a redistribution line over and electrically connecting to the first device die, wherein the first implantation process is performed on the dielectric liner, and is performed before the dielectric layer is deposited, and wherein the first device die comprises a through-via extending into the semiconductor substrate, and wherein a top end of the through-via is revealed after the dielectric layer is planarized.
